(19) United States
(12) Patent Application Publication
(10) Pub. No.: US 2010/0277212 A1
(43) Pub. Date: Nov. 4, 2010

(54) DELAY LOCKED LOOP

(75) Inventor: Sami Kallioinen, Espoo (FI)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/810,494

(22) PCT Filed: Dec. 19, 2008
(86) PCT No.: PCT/EP08/68001

§ 371 Date: Jun. 24, 2010

(30) Foreign Application Priority Data
Dec. 24, 2007 (GB) 0725242.2

(51) Int. Cl. H03L 7/06

(52) U.S. Cl. 327/158

(57) ABSTRACT

A delay locked loop comprises a delay line having a plurality of sequentially connected delay elements (E1 to E16). The delay line has an input for receiving an input signal and an output for outputting an output signal. A phase detector (6) is configured to detect a phase difference between the input signal and the output signal, and to generate a control signal based on said difference for supply to at least a part of the delay line. At least one further delay element (EO, E17). One of said at least one further delay element may be further configured to receive said control signal. A clock multiplier (4) can include such a delay locked loop.

The invention relates to a delay locked loop (DLL). The invention also relates to a clock multiplier including such a delay locked loop, and to a method in a delay locked loop.

Delay locked loops (DLLs) are typically used in clock distribution applications such as in a clock multiplier. A clock multiplier may, in turn, be used, for example, in complementary metal oxide semiconductor (CMOS)_chips. A clock multiplier can be used in a radio frequency integrated circuit (RFIC) design for a chip used, for example, in a receiver in a mobile terminal or other radio apparatus. Such a design can be used, for example, in continuous time sigma delta modulators (CT SDM) or in digital pulse width modulator (DPWM) architectures. The CT SDM is designed for use in Evolved-UMTS Terrestrial Radio Access Network (EUTRAN).

A DLL comprises a delay line of a plurality of sequentially connected delay elements. A phase detector can also be provided. Clock jitter is an important way to define quality of a clock multiplier. Clock jitter can be caused by longer or shorter than ideal delays between the phases of the clock input signals output by each delay element. Variable rising times in the clock input signals can contribute to such less than ideal delays. It may, in particular, become a problem that the environment at one or more nodes on a path of a clock input signal through the delay line is different to the environment at other nodes in the delay line. For example, at a first node and at a later node on a signal path the environments are different to environments at other nodes on that path. A block, that is, a component which drives a clock signal forward inside the circuit, for example, a buffer or inverter or another standard component capable of driving a capacitive load, at the first node from which the clock input signal is output may cause a different environment to the environments at the subsequent nodes. Notably, the block can be one of several components with respectively different driving capabilities and which respectively lead to different capacitive loads. Also, a delay element can be considered as a driving block since it drives a next delay element in a delay line and a time delay-input of a signal to the next delay element and the time delay causes capacitive load which has to be driven. At the last node, absence of a next delay element may lead to a different environment at the last node to the environments at the intermediate nodes. Different loads at the first and the last nodes can lead to different environments at these nodes, particularly if components are located between a driving component and the first node since in order to drive these components, it is necessary to drive more capacitive load. Slower signal rising results. The capacitive load input is also related to the size of an input transistor of the block.

Jitter in the clock multiplier can be a problem, for example, in CT SDM. It would therefore be desirable that jitter be reduced or eliminated to have a high quality of a multiplied clock signal.

According to the invention, there is provided a delay locked loop for a clock multiplier, comprising: a delay line having a plurality of sequentially connected delay elements, the delay line having an input for receiving an input signal and an output for outputting an output signal; a phase detector configured to detect a phase difference between the input signal and the output signal, and to generate a control signal based on said difference for supply to at least a part of the delay line; and at least one further delay element.

In an embodiment, a DDL further comprises a yet further delay element configured to output said input signal to the input of the delay line and to receive said control signal.

There is further provided a clock multiplier including a DLL provided according to the invention.

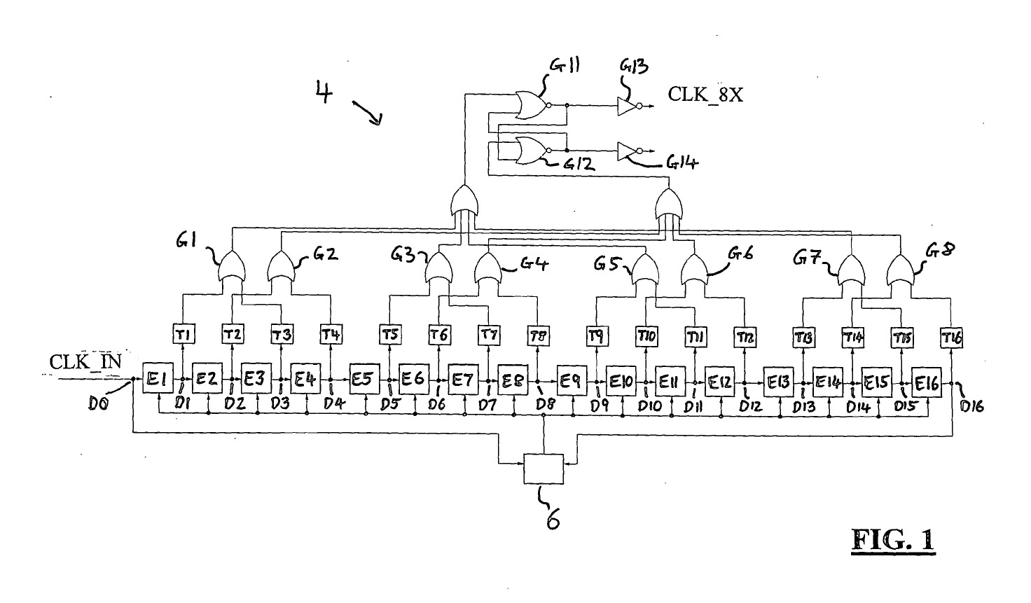

Use of such DLLs advantageously improves the quality of a multiplied clock signal since the multiplied clock signal has less systematic jitter. Advantageously, it is easy to modify a design of the known DLL shown in FIG. 1 to incorporate additional features of the present invention, and to modify manufacturing machines and processes to produce such a DLL or clock multiplier. Further, additional use of power and of chip area by such a DLL compared to the known DLL is insignificant.

According to the present invention, there is further provided a method in a delay locked loop, comprising: receiving a signal in a delay line, the delay line having a plurality of sequentially connected delay elements; processing said signal in said delay line and outputting said signal; detecting in a phase detector a phase difference between said signal before input to the delay line and following output from the delay line, and generating a control signal based on said phase difference; supplying said control signal to at least a part of the delay line; and supplying said signal to at least one further delay element.

According to the present invention, there is furthermore provided a computer readable medium in a phase detector that comprises executable instructions therein for execution by a processor, the instructions comprising: detecting a phase difference between two signals, and generating a control signal based on said difference; supplying said control signal to at least a part of a delay line; and supplying said signal to at least one further delay element.

To better understand the invention, an embodiment of the invention will now be described, by way of example only, in which:

FIG. 1 shows a clock multiplier;

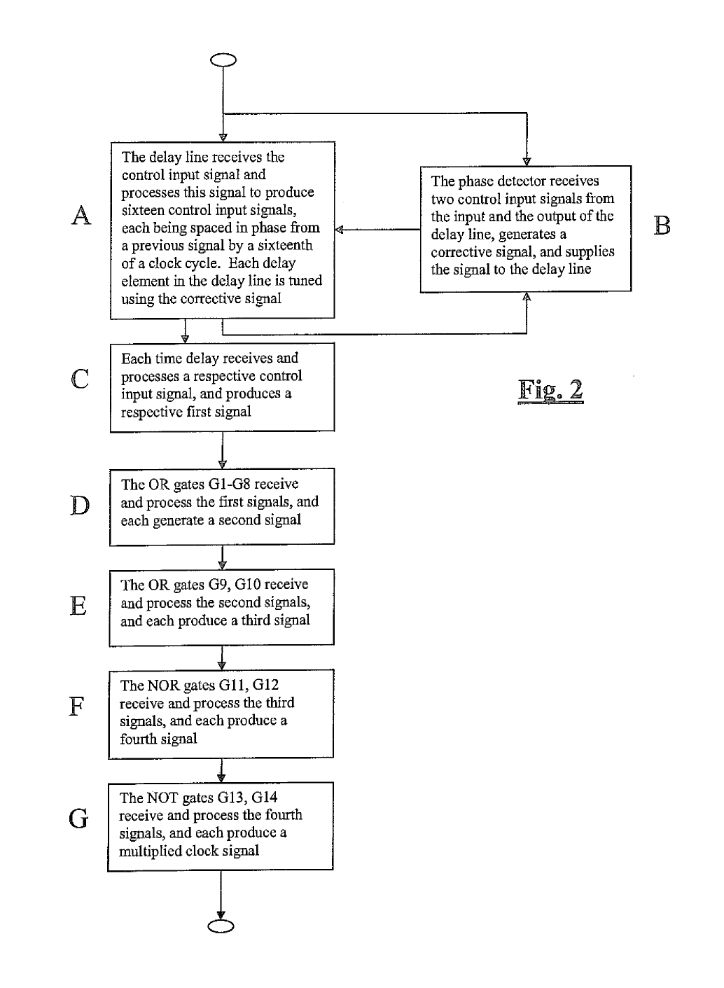

FIG. 2 is a flowchart to indicate signal flow in the clock multiplier;

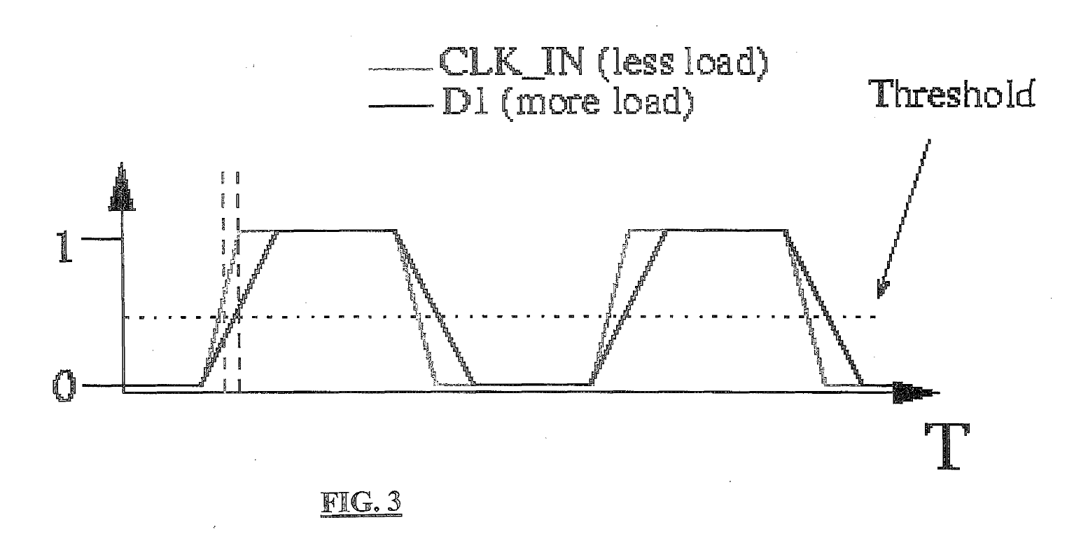

FIG. 3 shows rising times in such a known clock multiplier;

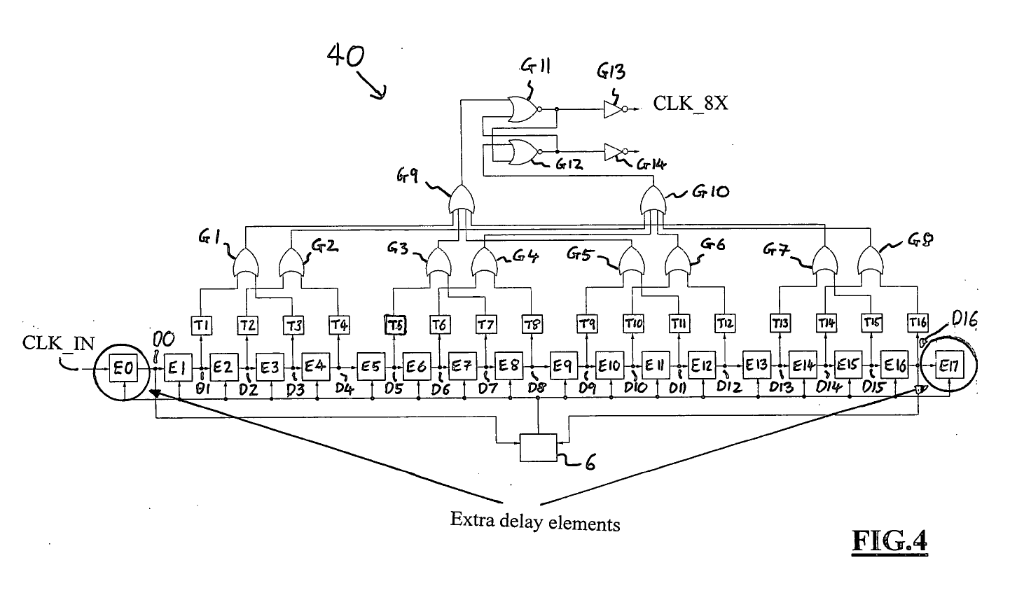

FIG. 4 shows a clock multiplier in accordance with the embodiment; and

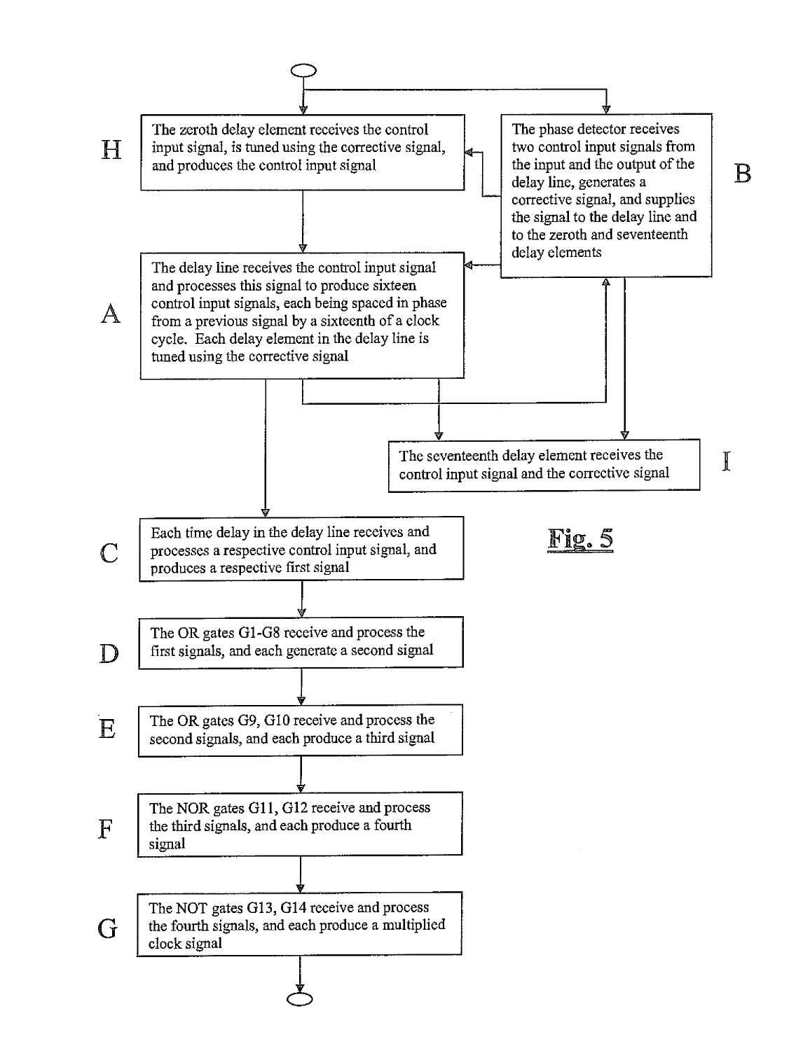

FIG. 5 is a flowchart in accordance with the embodiment.

Delay locked loops (DLLs) are used in clock distribution applications such as in clock multipliers. The clock multiplier may, in turn, be used, for example, in CMOS chips. FIG. 1 shows an example of such a clock multiplier 4.

The exemplifying DLL of FIG. 1 is shown to comprise a delay line of sixteen sequentially connected delay elements and a phase detector 6. These delay elements are respectively indicated as a first to a sixteenth delay element at E1 to E16.

Each delay element E1-E16 is of an appropriate design. Each delay element presents, with tuning by the phase detector 6, to a clock input signal a delay to the phase thereof of a sixteenth of a clock cycle. In this description the term “clock input signal” is used to refer throughout to a signal input to the DLL and that signal as it passes though the delay line including the signal output from the delay line. The delay line should therefore present a total delay of one clock cycle to the clock input signal input to the first delay elements E1 and allowed to follow a path sequentially through each of the delay elements E1-E16.

The phase detector 6 is connected to receive the clock input signal before input to the first delay element E1 and also the clock input signal following output by the sixteenth delay element 16. The phase detector 6 is for comparing these clock input signals and generating a corrective signal in the form of a control voltage for supply to each of the delay elements E1-E16 in order that any phase difference between the clock input signal before input to the delay line and after passing through the delay line can be brought towards zero.

The delay line further comprises sixteen nodes respectively indicated as a first node to a sixteenth node at D1 to D16, with each being located on the path of the clock input signal through the delay line so that the clock input signal passes through each node following output of the clock input signal from an associated delay element E1-E16. A further node D0 is located on the path of the clock input signal so that the clock input signal passes therethrough before being received at the input of the first delay element E1.

The clock multiplier further comprises sixteen time delays respectively indicated as a first time delay to a sixteenth time delay at T1 to T16. The time delays are for generating short pulses to be received by G1 to G15 in order to avoid overlapping of signals. The time delays T1-T16 are respectively connected to the delay line at the nodes D1-D16. The time delays T1-T16 are respectively connected to the nodes D1-D16 to receive the clock input signal in the different phases thereof from the delay elements E1-E16 via the nodes D1-D16.

Each time delay T1-T16 is for producing a first signal in the form of a narrow pulse from the clock input signal received thereat so that the first signals from the time delays T1-T16 are not up at the same time.

The time delays T1-T16 are connected to logic gates. An input side of a first OR gate G1 is connected to the first and the third time delays T1, T3. An input side of a second OR gate G2 is connected to the second and the fourth time delays T2, T4. An input side of a third OR gate G3 is connected to the fifth and the seventh time delays T5, T7. An input side of a fourth OR gate G4 is connected to the sixth and the eighth time delays T6, T8. An input side of a fifth OR gate G5 is connected to the ninth and the eleventh time delays T9, T11. An input side of a sixth OR gate G6 is connected to the tenth and the twelfth time delays T10, T12. An input side of a seventh OR gate G7 is connected to the thirteenth and the fifteenth time delays T13, T15. An input side of a eighth OR gate G8 is connected to the fourteenth and the sixteenth time delays T14, T16.

Output sides of the first, third, fifth and seventh OR gates G1, G3, G5, G7 are connected to an input side of a ninth OR gate G9. Similarly, output sides of the second, fourth, sixth and eighth OR gates G2, G4, G6, G8 are connected to an input side of a tenth OR gate G10.

An output side of the ninth OR gate G9 is connected to an input side of a first NOR gate G11. An output side of the tenth OR gate G10 is connected to an input side of a second NOR gate G12. An output side of the first NOR gate G11 is connected to the input side of the second NOR gate G12. An output side of the second NOR gate G12 is connected to the input side of the first NOR gate G11.

Additionally, the output sides of the first and second NOR gates G11, G12 are respectively connected to an input side of first and second NOT gates G13, G 14.

Operation of the clock multiplier is now described with reference to FIG. 2. The clock input signal is supplied to the first delay element E1, as indicated at step A. The time delay signal then passes through each of the second to the sixteenth time delay elements E2-E16 in turn.

At step B, the phase detector 6 receives the clock input signal in the phase that it is before input to the first delay element E1. The phase detector 6 also receives the clock input signal following output by the sixteenth delay element E16. The phase detector 6 then generates and supplies the corrective signal to each of the delay elements E1-E16 at step C.

The clock input signal output from each delay element E1-E16 is also received at the respective time delay T1-T16 via the respective one of said nodes D1-D16. Each clock input signal is different in phase to the clock input signal from an adjacent delay element E1-E15 by a sixteenth of a clock cycle.

Each time delay outputs a respective first signal in the form of a narrow pulse. At step D the first signals from the first and third time delays T1, T3 are received at the first OR gate G2. Similarly, the delay clock signals from the second and fourth time delays T2, T4 are received at the second OR gate G2, the clock signals from the fifth and seventh time delays T5, T7 are received at the third OR gate G3, the delayed clock signals from the eighth and the tenth time delays T8, T10 are received at the fourth OR gate G4, the delayed clock signals from the ninth and the eleventh time delays T9, T11 are received at the fifth OR gate G5, the delayed clock signals from the tenth and the twelfth time delays T10, T 12 are received at the sixth OR gate G6, the delayed clock signals from the thirteenth and the fifteenth time delays T13, T15 are received at the seventh OR gate G7, and the delayed clock signals from the fourteenth and the sixteenth time delays T14, T16 are received at the eighth OR gate G8. Since the first signals received at each OR gate G1-G8 are respectively an eight of a clock cycle apart in phase, each OR gate output signal has a duty cycle of five eighths.

At step E, second signals, one of which is output by each of the first, third, fifth and seventh OR gates G1, G3, G5, G7, are received at the ninth OR gate G9. Similarly, second signals, one of which is output by each of the second, fourth, sixth and eighth IR gates G2, G4, G6, G8, are received at the tenth OR gate G10.

At step F, third signals, one of which is output by each of the ninth and the tenth OR gates G9, G10, are respectively received at the first and the second NOR gate G11, G12.

At step G, fourth signals, one of which is output by each of the NOR gates G11, G12, are fed to the respective other of the NOR gates G11, G12, that is, a fourth output signal from the first NOR gate G11 is provided as an input signal to the second NOR gate G12, and a fourth output signal from the second NOR gate G12 is provided as an input signal to the first NOR gate G11.

Fourth signals, one of which is output from the first and second NOR gates, are also provided to respective NOT gates G13, G14.

Fifth output signals, one of which is output from each of the NOT gates G13, G14, have a clock cycle of an eighth of the clock cycle of the clock input signal.

As mentioned above, it may become a problem that at the zeroth node D0 and the sixteenth node D16, the respective environments thereat are different to environments at the first to fifteenth nodes D1-D15. At the zeroth node, a block (not shown) from which the clock input signal is output causes a different environment at the zeroth node D0 to the environments at the first to fifteenth nodes D1-D15. At the sixteenth node, absence of a block leads to a different environment at the sixteenth node to the environments at the first to fifteenth nodes D1-D15. Different load at the zeroth and the sixteenth nodes D0, D16 can also lead to a different environment at these nodes.

FIG. 3 shows rising times at the zeroth node D0 of a clock input signal, indicated by the “CLK_IN” signal, and at the first node D1 in the clock multiplier of FIG. 1. The rising time at the zeroth node D0 is faster than at the first node D1. The rising time at D1 is similar to the rising times at the second to fifteenth nodes D2-D15 since the environments at these nodes are similar or substantially the same. The faster rising time at the zeroth node leads to jitter.

A clock multiplier is an important component in an RFIC design for a chip used, for example, in a receiver in a mobile terminal. The following explains an exemplifying embodiment how it can be possible to have a higher quality of a multiplied clock signal.

FIG. 4 shows a clock multiplier 40 provided with all of the elements of the clock multiplier 4 of FIG. 1. Such elements are designated with the same reference numerals and are generally therefore not described further except where the operation of such elements deviates from the operation described above.

In the embodiment shown in FIG. 4, the delay line is provided with a zeroth delay element E0 for receiving the clock input signal and for supply to the clock input signal to the first delay element E1. The zeroth node D0 is located on the path of the clock input signal from the zeroth delay element E0 to the first delay element E1.

The delay line is also provided with a seventeenth delay element E17 for receiving the clock input signal from the sixteenth delay element E16.

The zeroth and the seventeenth delay elements E0, E17 are connected to the phase detector 6 to allow receipt of the corrective signal.

Operation of the clock multiplier of FIG. 4 will now be described with reference to FIG. 5. Steps described above with reference to FIG. 2 are designated with the same reference numerals and are generally therefore not described further except where such steps differ from the steps described above.

Indicated at step I-I, the clock input signal is provided to the zeroth delay element E0 and thereafter is supplied by the zeroth delay element E0 towards the zeroth node D0. The clock input signal passes sequentially through the first to sixteenth delay elements E1-E16 in the same way as described in steps A, and C to G described with reference to FIG. 2 so as to result in multiplied clock signals being output at the thirteenth and fourteenth gates G13, G14. Step B is modified so that the corrective signal is supplied to the zeroth and the seventeenth delay elements E0, E17 in addition to the delay elements E1-E16 in the delay line. At step I, the seventeenth delay element E17 receives the control input signal and the corrective signal.

The zeroth delay element E0 causes an environment at the zeroth node D0, that is, between the zeroth delay element E0 and the first delay element E1, which is similar to an environment at the first to the fifteenth nodes D1-D15.

Similarly, the seventeenth delay element E17 causes an environment at the seventeenth node D16, that is, between the sixteenth delay element E16 and the seventeenth delay element E17, which is similar to the environment at the first to the fifteenth nodes D1-D15.

Reduced jitter in the multiplied clock signal will result.

Additionally, the clock input signal received by the phase detector 6 via the zeroth node D0 and the clock input signal received by the phase detector 6 via the seventeenth node D17 will be such as to allow the phase detector 6 to determine more accurately any phase difference between the clock input signal at these nodes, and to generate an improved corrective signal accordingly. This will also lead to reduced jitter in the multiplied clock signal.

It will be appreciated that, while in the embodiment described the clock multiplier multiplies by a factor of eight, the invention can be readily used in clock multipliers that multiply by other factors, such as two, four, sixteen or higher. A delay line, which is described above as comprising delay elements E1 to E16, does not have to comprise sixteen delay elements—the delay locked loop can be modified to include any even number of delay elements.

It will also be appreciated that, while in the embodiment described the corrective signal from the phase detector 6 is supplied to all delay elements E0-E17, the DLL may operate satisfactorily if the phase detector 6 is only connected to some of the delay elements E0-E17.

Since the environments at the zeroth and sixteenth nodes D0, D16 are more similar to the environments at the first to fifteenth nodes than in the DLL of FIG. 1, the rising time in the clock input signal at the zeroth and sixteenth nodes D0, D16 is more similar, or indeed substantially the same as, the rising time in the clock input signal at the first to sixteenth nodes D1, D16.

The phase detector may be provided in various manners.

It is possible to provide at least a part of the above operations by means of an appropriate software product. The data processing functions may be provided by means of one or more data processors. The above described functions may be provided by separate processors or by an integrated processor. An appropriately adapted computer program code product or products may be used for implementing the embodiments, when loaded on an appropriate processor, for example in a processor of a communication device. The program code means may, for example, perform the generation and/interpretation of the control signal. The program code product for providing the operation may be stored on and provided by means of a carrier medium such as a carrier disc, card or tape. A possibility is to download the program code product to the mobile device via a data network.

The DLL described above can be used in various applications. A non-limiting example of such an application is in a digital pulse width modulator (DPWM) architecture in digital devices such as a field-programmable gate array (FPGA). A DLL is used to multiply clock frequency so that a high clock frequency, that is, the multiplied clock frequency, can be used internally in the DPWM in the device while the frequency of the input clock signal which is at a lower frequency can be used in the rest of the digital device. This is very useful, since counter-based DPWM found in such an architecture is very simple, but other blocks in such a device are often more complex and require lower frequencies than the DPWM. The DLL also allows multiplication of time resolution beyond the maximum resolution achievable with a counter-based technique.

Further, a DLL can be used to control cell delay, or to enable synchronisation to an external clock, for delay-line based DPWM cells. Additionally, a DLL based arrangement can be used to generate multiphase pulse width modulator signals.

It is noted that whilst embodiments have been described in relation to mobile and other communication devices, embodiments of the present invention are applicable to any other suitable type of apparatus where clock jitter may cause a problem.

It is also noted herein that while the above describes exemplifying embodiments of the invention, there are several variations and modifications which may be made to the disclosed solution without departing from the scope of the present invention.

1.-10. (canceled)

11. A delay locked loop comprising:
a delay line having a plurality of sequentially connected delay elements, the delay line having an input for receiving an input signal and an output for outputting an output signal;
a phase detector configured to detect a phase difference between the input signal and the output signal, and to generate a control signal based on said difference for supply to at least a part of the delay line; and
at least one further delay element configured to provide the input signal and receive the output signal, and connected to the phase detector.

12. A delay locked loop according to claim 11, wherein one of said at least one further delay element is further configured to receive said control signal.

13. A delay locked loop according to claim 11, wherein the input signal is a clock input signal, and one of said at least one further delay element is configured to receive the clock input signal and output the clock input signal to the input of the delay line and to receive said control signal.

14. A delay locked loop according to claim 11, wherein the delay locked loop is configured to allow said input signal to pass through said further delay element and then through each of said plurality of delay elements in turn.

15. A delay locked loop according to claim 11, wherein each of said delay elements and said further delay element provide substantially a same delay.

16. A clock multiplier including a delay locked loop according to claim 11.

17. A method in a delay locked loop, comprising:
receiving a signal in a delay line, the delay line having a plurality of sequentially connected delay elements;
processing said signal in said delay line and outputting said signal;
detecting in a phase detector a phase difference between said signal before input to the delay line and following output from the delay line, and generating a control signal based on said phase difference;
supplying said control signal to at least a part of the delay line; and
supplying said signal to at least one further delay element connected to the delay line and the phase detector.

18. A method according to claim 17, further comprising supplying said control signal to said at least one further delay element.

19. A method according to claim 17, wherein supplying said signal to at least one further delay element comprises supplying said signal to a further delay element, said further delay element then supplying said signal to said delay line.

20. A computer-readable medium encoded with instructions that, when executed by a computer, perform:
detecting a phase difference between an input signal to a delay line and an output signal from the delay line, and generating a control signal based on said difference;
supplying said control signal to at least a part of the delay line; and
supplying said control signal to at least one further delay element connected to the delay line.
